(19) United States
(12) Patent Application Publication
(10) Pub. No.: US 2026/0305370 A1
(43) Pub. Date: Oct. 1, 2026

(54) SEMICONDUCTOR DEVICE AND FABRICATION METHOD THEREOF

(71) Applicant: Yangtze Memory Technologies Co., Ltd., Wuhan (CN)

(72) Inventor: Cong LU, Wuhan (CN)

(21) Appl. No.: 19/223,926

(22) Filed: May 30, 2025

(30) Foreign Application Priority Data
Apr. 1, 2025 (CN) 202510402816.5

(51) Int. Cl. H10W 46/00

(52) U.S. Cl. CPC H10W 46/00; H10W 46/301

(57) ABSTRACT

Methods, devices, systems, and techniques for managing optical measurement marks in semiconductor devices are provided. In one aspect, a semiconductor device includes a first region, where the first region includes first semiconductor bodies; a first dielectric layer stacked on the first semiconductor bodies; and first via structures extending along a first direction into the first dielectric layer, where the first via structures are spaced apart from each other along a second direction and a third direction that are perpendicular to the first direction. The semiconductor device also includes a second region adjacent to the first region along the second direction, where the second region includes memory cells having second semiconductor bodies.

### CROSS-REFERENCE TO RELATED APPLICATIONS

This application claims priority to Chinese Patent Application No. 202510402816.5, filed on Apr. 01, 2025, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures, e.g., vertical transistors.

### SUMMARY

The present disclosure describes methods, devices, systems and techniques for managing vertical structures in three-dimensional (3D) semiconductor devices.

One aspect of the present disclosure features a semiconductor device. The semiconductor device includes a first region, where the first region includes first semiconductor bodies; a first dielectric layer stacked on the first semiconductor bodies; and first via structures extending along a first direction into the first dielectric layer, where the first via structures are spaced apart from each other along a second direction and a third direction that are perpendicular to the first direction. The semiconductor device also includes a second region adjacent to the first region along the second direction, where the second region includes memory cells having second semiconductor bodies.

In some implementations, a sum of areas of cross-sections of the first via structures in a unit area of an overlay (OVL) measurement of the first region occupies at least 30% of the unit area, where the unit area is perpendicular to the first direction.

In some implementations, the first semiconductor bodies extend along the first direction, and where a portion of the first semiconductor bodies closer to the first dielectric layer are connected together along the second direction.

In some implementations, the first via structures are arranged in rows extending along the second direction and in columns extending along the third direction.

In some implementations, the rows of the first via structures are arranged in a staggered pattern.

In some implementations, a length of the rows of the first via structures is less than or equal to a length of the first region along the second direction, and where a length of the columns of the first via structures is at least 25 µm along the third direction.

In some implementations, the first region includes a first conductive line stacked on the first semiconductor bodies, where the first conductive line is between the first semiconductor bodies and the first dielectric layer along the first direction, and where the first conductive line extends along the second direction; and second conductive lines extending along the third direction, where at least one of the second conductive lines are between two adjacent first semiconductor bodies along the second direction.

In some implementations, along the third direction, one or more of the second conductive lines are between two adjacent first via structures.

In some implementations, the memory cells in the second region are arranged in to one or more blocks, and where each of the one or more blocks includes a core region including an array of the memory cells and a surrounding region that surrounds the core region.

In some implementations, each of the one or more blocks further includes a second dielectric layer stacked on the second semiconductor bodies of the memory cells; a bit line stacked on the second semiconductor bodies, where the bit line is between the second semiconductor bodies and the second dielectric layer along the first direction, and where the bit line extends along the second direction; and word lines extending along the third direction, where at least one of the word lines is between two adjacent second semiconductor bodies along the second direction.

In some implementations, the surrounding region includes second via structures extending along the first direction, where the second via structures extend through the second dielectric layer, and where the second via structures are spaced apart from each other along the second direction and the third direction.

In some implementations, the bit line is coupled to a peripheral circuit through a corresponding one of the second via structures in the surrounding region, and where each of the word lines is coupled to the peripheral circuit through a corresponding one of the second via structures in the surrounding region.

In some implementations, a sum of areas of cross-sections of the second via structures in a unit area of an OVL measurement of the surrounding region is less than or equal to 10% of an area of the unit area, where the unit area is perpendicular to the first direction.

In some implementations, along the second direction, a distance between two adjacent first via structures in the first region is substantially same as a distance between two adjacent second via structures in the surrounding region of the second region.

In some implementations, an area of a cross-section of each of the first via structures is substantially equals to an area of a cross-section of each of the second via structures.

Another aspect of the present disclosure features a method of forming a semiconductor device. The method includes forming a first region, where the first region includes: first semiconductor bodies; a first dielectric layer stacked on the first semiconductor bodies; and first via structures extending along a first direction into the first dielectric layer, where the first via structures are spaced apart from each other along a second direction and a third direction that are perpendicular to the first direction. The method also includes forming a second region adjacent to the first region along the second direction, where the second region includes memory cells having second semiconductor bodies.

In some implementations, forming the first via structures in the first region includes providing a substrate including the first semiconductor bodies; depositing a dielectric material on the first semiconductor bodies to form the first dielectric layer; etching a portion of the first dielectric layer to form first holes; and filling the first holes with a conductive material to form the first via structures.

In some implementations, a sum of areas of cross-sections of the first holes in a unit area of an overlay (OVL) measurement of the first region occupies at least 30% of the unit area, where the unit area is perpendicular to the first direction.

In some implementations, the first holes are arranged in rows extending along the second direction and in columns extending along the third direction, and a length of the rows of the first holes is less than or equal to a length of the first region along the second direction, and where a length of the columns of the first holes is at least 25 µm along the third direction.

A further aspect of the present disclosure features a memory system. The memory system includes a memory device; and a memory controller coupled to the memory device and configured to control the memory device, where the memory device includes a first region, where the first region includes first semiconductor bodies; a first dielectric layer stacked on the first semiconductor bodies; and first via structures extending along a first direction into the first dielectric layer, where the first via structures are spaced apart from each other along a second direction and a third direction that are perpendicular to the first direction. The memory device also includes a second region adjacent to the first region along the second direction, where the second region includes memory cells having second semiconductor bodies.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a top view of an example semiconductor device.

FIG. 2A illustrates a top view of an example semiconductor device.

FIG. 2B illustrates a cross-section view of the example semiconductor device of FIG. 2A.

FIG. 2C illustrates a top view of an example semiconductor device.

FIG. 2D illustrates a cross-section view of the example semiconductor device of FIG. 2C.

FIGS. 3A to 3D show cross-sectional views of structures of a semiconductor device of FIG. 2A at various stages of a fabrication process.

FIG. 4 illustrates a flow chart of an example semiconductor structure manufacturing process.

FIG. 5 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, optical measurement of overlay marks is desired for process control during the fabrication of a memory device (e.g., a DRAM memory) with different blocks of memory cells. The layout of the overlay marks may pose challenges during the fabrication and testing process. For example, the overlay marks in the current memory device may not provide a reliable optical reading during the fabrication process. The unreliable readings may increase defects during fabrication, which in turn, increases the fabrication cost. Additionally, the overlay marks in the current design surround each block of memory cells, which may increase the difficulty of locating the overlay marks during the fabrication and testing processes. Therefore, an overlay mark design that can solve the aforementioned issues is desirable.

In one or more implementations of the present disclosure, an example semiconductor device is provided. The semiconductor device includes a first region that includes first semiconductor bodies, a first dielectric layer stacked on the first semiconductor bodies, and first via structures extending along a first direction into the first dielectric layer, where the first via structures are spaced apart from each other along a second direction and a third direction that are perpendicular to the first direction. The semiconductor device also includes a second region adjacent to the first region along the second direction, where the second region includes memory cells having second semiconductor bodies.

Implementations of the present disclosure can provide one or more of the following technical advantages and/or benefits. First, a portion of the overlay marks can be arranged in an array in the dummy region of the memory device. This portion of the overlay marks has a higher density than the current design. In other words, the overlay marks in the present disclosure can be used for accurate optical overlay measurement during the fabrication and testing process, which lowers the defects of the memory device. Second, this portion of the overlay marks is located in a dedicated region, allowing the measurement tool to accurately locate each array of overlay marks. Third, another portion of the overlay marks can be used as a connection structure between the memory device and a peripheral circuit. In other words, this portion of the overlay marks can be used to control the memory cells of the memory device. Additionally, this approach allows for easier process implementation and improved control during manufacturing, thereby enhancing manufacturing reliability and increasing the overall production yield.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

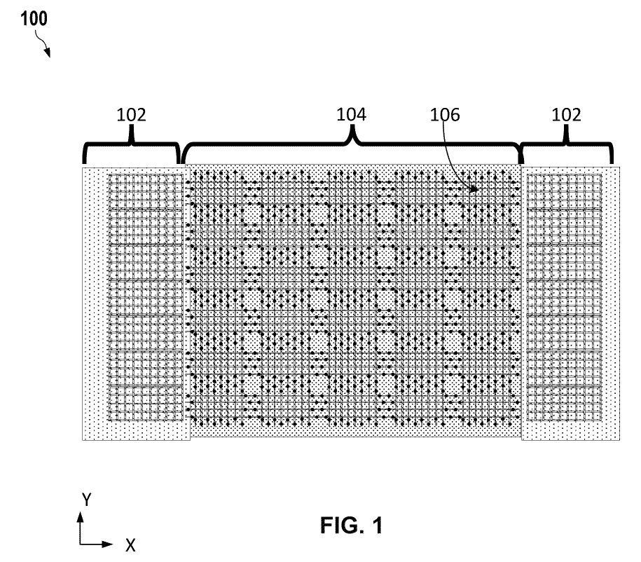

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a top view of a semiconductor device 100. The semiconductor device 100 can be a 3D dynamic random-access memory (DRAM). It is understood that FIG. 1 is for illustrative purposes only and may not necessarily reflect the actual device structure (e.g., interconnections) in practice.

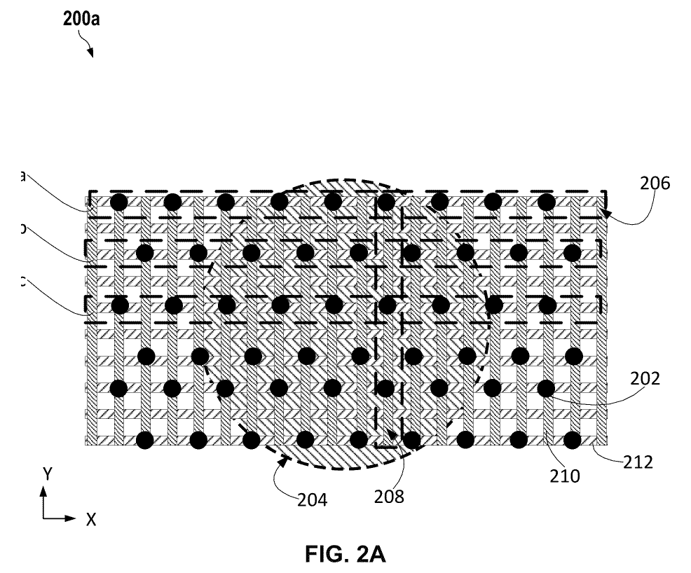

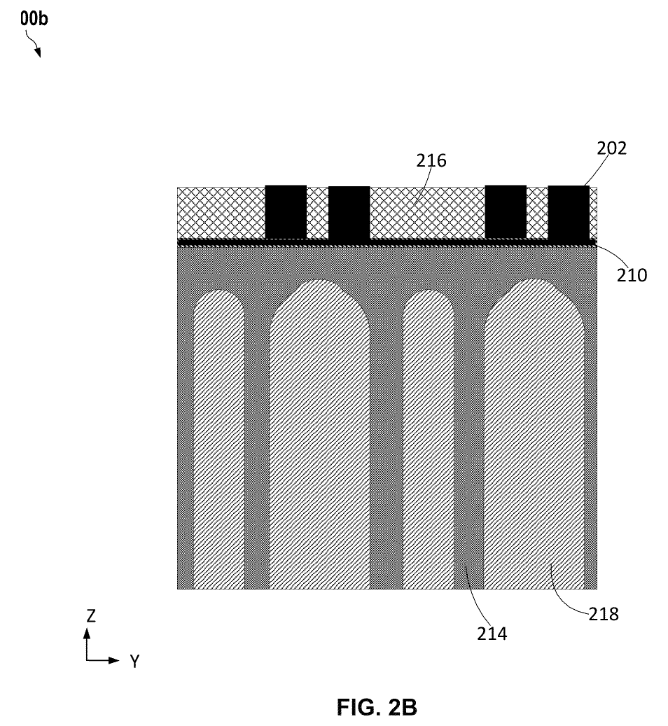

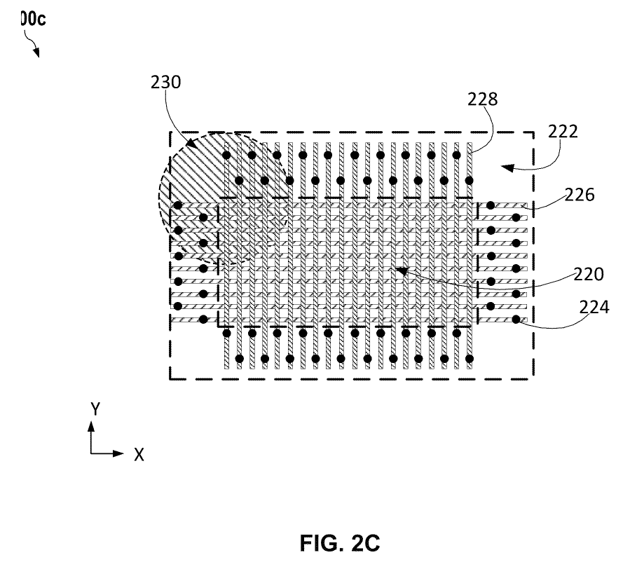

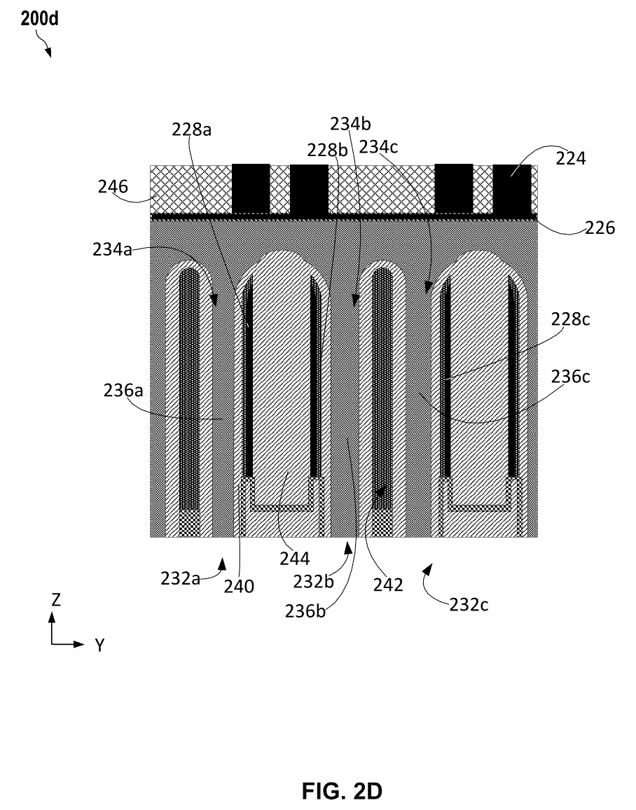

As shown in FIG. 1, the semiconductor device 100 includes at least a first region 102 and at least a second region 104. The second region 104 is adjacent to the first region 102 along a horizontal direction (e.g., the X direction). In some implementations, the first region 102 can be referred to as a dummy region, and the second region 104 can be referred to as a memory region. In some implementations (as shown in FIG. 2C), the second region 104 can include memory cells. Each of the memory cells includes a semiconductor body extending along a vertical direction (e.g., the Z direction) perpendicular to the X direction and a gate structure that is coupled to the semiconductor body. In some implementations (as shown in FIG. 2C), the first region 102 can include semiconductor bodies extending along the Z direction, where two adjacent semiconductor bodies are separated by a dielectric structure.

As shown in FIG. 1, the semiconductor device 100 can include two first regions 102 and one second region 104. The second region 104 is between the two first regions 102 along the X direction. The semiconductor device 100 can include any combinations of the first region 102 and the second region 104. For example, the semiconductor device 100 can include two second regions 104 and one first region 102, where the first region 102 is between the two second regions 104 along the X direction. In another example, the semiconductor device 100 can include one first region 102 and one second region 104. As shown in FIG. 1, the second region 104 can include one or more blocks 106. Each of the one or more blocks 106 includes a core region having memory cells and a surrounding region that surrounds the core region (e.g., the core region 220 and the surrounding region 222 as shown in FIG. 2C).

FIG. 2A illustrates a top view of an example semiconductor device 200a. The semiconductor device 200a can be a portion of the first region 102 of the semiconductor device 100 of FIG. 1. As shown in FIG. 2A, the semiconductor device 200a includes first via structures 202 extending along the Z direction. The first via structures 202 are spaced apart from each other along horizontal directions (e.g., the X direction and the Y direction) perpendicular to the Z direction. A cross-section of the first via structures 202 perpendicular to the Z direction can include but not limit to a circular shape, a square shape, an ellipse shape or any other suitable shapes. As shown in FIG. 2A, a sum of areas of cross-sections of the first via structures 202 in a unit area 204 of an overlay (OVL) measurement of the semiconductor device 200a occupies at least 30% of the unit area 204. The unit area 204 is perpendicular to the Z direction. In some implementations, the first via structures 202 can be used as alignment mark during fabrication and testing process of the semiconductor device 200a. The high density of the first via structures 202 ensures a precise measurement of the OVL measurement which ensures an accurate positioning of the semiconductor device 200a during the fabrication and testing process.

As shown in FIG. 2A, the first via structures are arranged in rows 206 extending along the X direction and columns 208 extending along the Y direction. The rows 206 of the first via structures 202 are arranged in a staggered pattern. For example, as shown in FIG. 2A, the rows 206 of the first via structures 202 includes a first row 206a, a second row 206b, and a third row 206c. First via structures 202 of the first row 206a and first via structures 202 of the third row 206c are aligned along the X direction, whereas the first via structures 202 of the first row 206a and first via structures 202 of the second row 206b are offset along the X direction. In some implementations, a length of each of the rows 206 of the first via structures 202 is less than or equal to a length of the semiconductor device 200a along the X direction. A length of each of the columns 208 of the first via structures 202 is at least 25µm along the Y direction. The length of the each of the rows 206 and each of the columns 208 of the first via structures 202 ensures the unit area 204 of the OVL measurement can be positioned inside the rows 206 and columns 208 of the first via structure 202 of the semiconductor device 200a during an optical measurement process. The semiconductor device 200a includes first conductive lines 210 that extend along the Y direction and second conductive lines 212 that extend along the X direction. In some implementations, as shown in FIG. 2A, one or more second conductive lines 212 are between two adjacent two adjacent first via structures 202 in each of the columns 208 along the Y direction.

FIG. 2B illustrates a cross-section view of an example semiconductor device 200b. In some implementations, the semiconductor device 200b can be a part of the semiconductor device 200a or formed at an intermediate step of fabricating the semiconductor device 200a of FIG. 2A. In some implementations, the semiconductor device 200b can be an embodiment of the semiconductor device 200a. It is understood that the semiconductor device 200b as shown in FIG. 2B is for illustration propose only, and the semiconductor device 200b can have various arrangements of the first via structures 202 that are not shown in FIG. 2B.

As shown in FIG. 2B, the semiconductor device 200b includes first semiconductor bodies 214 extending along the Z direction. The semiconductor device 200b also includes a first dielectric layer 216 stacked on the first semiconductor bodies 214 along the Z direction. The first via structures 202 extend into the first dielectric layer 216 along the Z direction. In some implementations, a first portion of the first semiconductor bodies 214 are spaced by dielectric structures 218 along the Y direction, and a second portion of the first semiconductor bodies 214 closer to the first dielectric layer 216 are connected together along the Y direction.

In some implementations, as shown in FIG. 2B, the first via structures extend through the first dielectric layer 216 and are in contact with the first conductive line 210. In some implementations (not shown in FIG. 2B), the first via structures 202 extend into the first dielectric layer 216 without contact the first conductive line 210. In some implementations (not shown in FIG. 2B), the semiconductor device 200b further includes second conductive lines (e.g., the second conductive lines 212 of FIG. 2A) extend into a portion of the dielectric structure 218 along the Z direction, and the first via structures 202 extend through the first dielectric layer 216 into the dielectric structure 218, where the first via structures 202 are in contact with corresponding second conductive lines. In some implementations, the first via structures 202 can have various depth. In one example, a first portion of the first via structures 202 extend through the first dielectric layer 216 and are in contact with the first conductive line 210 and a second portion of the first via structures 202 extend through the first dielectric layer 216 and the first conductive line 210 and are in contact with the second conductive lines. In another example, a first portion of the first via structures 202 extend into the first dielectric layer 216 without contact the first conductive line 210, a second portion of the first via structures 202 extend through the first dielectric layer 216 and are in contact with the first conductive line 210, and a third portion of the first via structures 202 extend through the first dielectric layer 216 and are in contact with corresponding second conductive lines without contacting the first conductive line 210.

In some implementations, the first via structures 202 can include a conductive material including, but not limited to, W, Co, Cu, Al, TiN, TaN, or any combination thereof. In some implementations, the first dielectric layer 216 can include a dielectric material including, but not limited to, SiO2, HfO2, SiN, Al2O3, HfO2, Ta2O5, ZrO2, TiO2, or any combination thereof. In some implementations, the first semiconductor body 214 can include a semiconductor material such as Poly-Si. In some implementations, the first conductive line 210 can include a conductive material including, but not limited to, W, Co, Cu, Al, TiN, TaN, metal silicide, or any combination thereof. In some implementations, the first conductive line 210 can include a metalized semiconductor material such as doped poly silicon.

FIG. 2C illustrates a top view of an example semiconductor device 200c. The semiconductor device 200c can be a block 106 of the second region 104 of the semiconductor device 100 of FIG. 1.

As shown in FIG. 2C, the semiconductor device 200c includes a core region 220 and a surrounding region 222 that surrounds the core region 220. The core region 220 of the semiconductor device 200c includes an array of the memory cells (e.g., DRAM cell as shown in FIG. 2D). The surrounding region 222 includes the second via structures 224. The second via structures 224 are spaced apart from each other along the X direction and the Y direction.

The semiconductor device 200c also includes bit lines 226 and word lines 228. The bit lines 226 extend through the core region 220 and the surrounding region 222 along the Y direction. The word lines 228 extend through the core region 220 and the surrounding region 222 along the X direction. In some implementations, as shown in FIG. 2C, each of the bit lines 226 is coupled to a peripheral circuit through a corresponding one of the second via structures 224 in the surrounding region 222, and each of the word lines 228 is coupled to the peripheral circuit through a corresponding one of the second via structures 224 in the surrounding region. In some implementations, a portion of the second via structures 224 that are connected to the bit lines 226 and the word lines 228 can be used as a contact structure that transfer signal between the peripheral circuit and the bit lines 226 and the word lines 228 during an operation of the array of memory cells in the core region 220.

A cross-section of the second via structures 224 perpendicular to the Z direction can include but not limit to a circular shape, a square shape, an ellipse shape or any other suitable shapes. For example, the cross-section of the first via structures 202 and the cross-section of the second via structure 224 can both include a circular shape. As shown in FIG. 2C, a sum of areas of cross-sections of the second via structures 224 in a unit area 230 of an OVL measurement of the surrounding region is less than or equal to 10% of an area of the unit area 230. The unit area 230 is perpendicular to the Z direction. In some implementations, an area of the unit area 204 of the semiconductor device 200a of FIG. 2A is substantially equal to an area of the unit area 230 of the semiconductor device 200c of FIG. 2C along a plane perpendicular to the Z direction. In some implementations, a distance between two adjacent first via structures 202 is substantially same as a distance between two adjacent second via structures 224 along the Y direction. In some implementations, the first via structures 202 and the second via structures 224 can be formed in a single fabrication step, where the cross-section of the first via structures 202 and the cross-section of the second via structures 224 can include a same shape. In some implementations, an area of the cross-section of each of the first via structures 202 is substantially equals to an area of the cross-section of each of the second via structures 224. In some implementations, a density of the first via structures 202 of the semiconductor device 200a in a unit area is greater than a density of the second via structures 224 of the semiconductor device 200c in the unit area.

FIG. 2D illustrates a cross-section view of an example semiconductor device 200d. In some implementations, the semiconductor device 200d can be a part of the semiconductor device 200c or formed at an intermediate step of fabricating the semiconductor device 200c of FIG. 2C. In some implementations, the semiconductor device 200d can be an embodiment of the semiconductor device 200c. It is understood that the semiconductor device 200d as shown in FIG. 2B is for illustration propose only, and the semiconductor device 200d can have various arrangements of the second via structures 224 that are not shown in FIG. 2D.

As shown in FIG. 2D, the semiconductor device 200c includes an array of memory cells 232. Each of the memory cells 232 includes a vertical transistor 234 having a second semiconductor body 236 extends along the Z direction and a word line 228 coupled to the second semiconductor body 236. The word line 228 extends along the X direction. In some implementations, as shown in FIG. 2D, the word line 228 are separated from a corresponding second semiconductor body 236 by a dielectric layer 240 along the Y direction. The bit line 226 is stacked on the vertical transistors 234 of the memory cells 232 along the Z direction. In some implementations, two adjacent word lines 228 of two adjacent vertical transistors 234 are separated by a dielectric body 242 along the Y direction. In some implementations, two semiconductor bodies 236 of two vertical transistors 234 are separated by an isolation structure 244 along the Y direction. For example, as shown in FIG. 2D, the semiconductor device 200c includes memory cells 232a, 232b, and 232c. The memory cells 232a, 232b, and 232c includes vertical transistors 234a, 234b, and 234c having second semiconductor bodies 236a, 236b, and 236c coupled to corresponding word lines 228a, 228b, and 228c. As shown in FIG. 2D, the word lines 228a and 228b are separated by the dielectric body 242. The second semiconductor bodies 236b and 236c are separated by the isolation structure 244.

The semiconductor device 200c also includes a second dielectric layer 246 stacked on the bit line 226. As shown in FIG. 2D, the bit line 226 is between the second semiconductor bodies 236 and the second dielectric layer 246 along the Z direction. In some implementations, the second via structures 224 extend through the second dielectric layer 246 along the Z direction. In some implementations, as shown in FIG. 2D, the second via structures 224 are in contact with the bit line 226 along the Z direction. In some implementations (not shown in FIG. 2D), the second via structures 224 are in contact with corresponding word lines 228. In some implementations, the second via structures 224 can have various depth. In one example, a first portion of the second via structures 224 extend through the second dielectric layer 246 and are in contact with the bit line 226 and a second portion of the second via structures 224 extend through the second dielectric layer 246 and are in contact with the word lines 228 without contacting bit line 226. In another example, a first portion of the second via structures 224 extend into the second dielectric layer 246 without contacting the bit line 226, a second portion of the second via structures 224 extend through the second dielectric layer 246 and are in contact with the bit line 226, and a third portion of the second via structures 224 extend through the second dielectric layer 246 and are in contact with corresponding word lines 228 without contacting the bit line 226.

In some implementations, each of the memory cells 232 of the semiconductor device 200c further includes a storage structure such as a capacitor to store memory data. The storage structure of each of the memory cells 232 is connected to a corresponding second semiconductor body 236 of the memory cell 232 along the Z direction. In some implementations, the bit line 226 and the storage structure are at an opposite end of the corresponding second semiconductor body 236 along the Z direction. In some implementations, the second via structures 224 connected to the bit line 226 and the word lines 228 can be used to transfer data between a peripheral circuit to the corresponding bit line 226 and the word lines 228 to control the memory cells 232.

In some implementations, the second via structures 224 can include a conductive material including, but not limited to, W, Co, Cu, Al, TiN, TaN, or any combination thereof. In some implementations, the first via structures 202 and the second via structures 224 can include a same conductive material. For example, the first via structures 202 and the second via structures 224 can include W. In some implementations, the second dielectric layer 246 can include a dielectric material including, but not limited to, SiO2, HfO2, SiN, Al2O3, HfO2, Ta2O5, ZrO2, TiO2, or any combination thereof. In some implementations, the first dielectric layer 216 and the second dielectric layer 246 can include a same dielectric material such as SiO2. In some implementations, the second semiconductor body 236 can include a semiconductor material such as Poly-Si. In some implementations, the word lines 228 can include a conductive material including, but not limited to, W, Co, Cu, Al, TiN, TaN, or any combination thereof. In some implementations, the bit line 226 can include a conductive material including, but not limited to, W, Co, Cu, Al, TiN, TaN, or any combination thereof. In some implementations, the bit line 226 can include a metalized semiconductor material such as doped poly silicon.

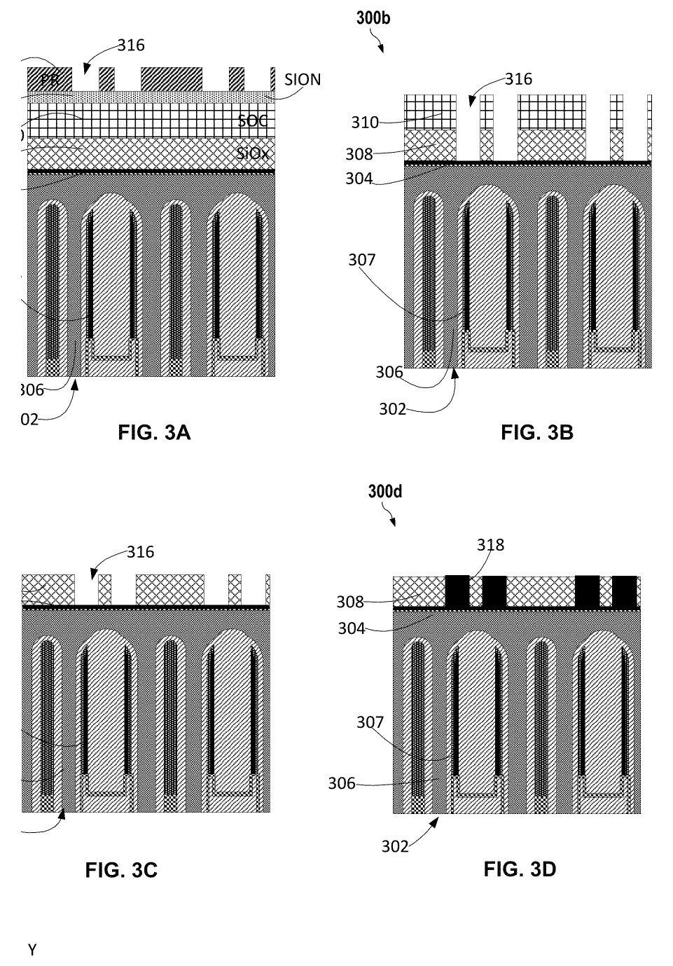

FIGS. 3A – 3D illustrate an example process of fabricating a semiconductor device, such as the semiconductor device 200a as illustrated in FIGS. 2A – 2B or the semiconductor device 200c as illustrated in FIGS. 2C – 2D. FIGS. 3A – 3D show cross sectional views of example semiconductor structures at various stages of the fabrication process.

As shown in FIG. 3A, a semiconductor structure 300a is formed. The semiconductor structures 300a includes a semiconductor structure 302 and a conductive layer 304 stack on top of the semiconductor structure 302. In some implementations, the semiconductor structure 302 can be an array of memory cells. Each of the array of the memory cells can include a semiconductor body 306 and a word line 307 couple to the each of the array of the memory cells. The semiconductor structure 302 also includes a first dielectric layer 308 stacked on top of the conductive layer 304 along the Z direction, a hard mask layer 310 stacked on top of the first dielectric layer 308, a second dielectric layer 312 stacked on top of the hard mask layer 310, and a sacrificial layer 314 stacked on top of the second dielectric layer 312. As shown in FIG. 3A, the semiconductor structure 300a includes first trenches 316, which can be formed by etching a portion of the sacrificial layer 314 along the Z direction. In some implementations, the semiconductor structure 300a does not include the conductive layer 304, where the first dielectric layer 308 is stacked on top of the semiconductor structure 302 along the Z direction.

FIG. 3B illustrate a semiconductor structure 300b, which can be formed by deepening the first trenches 316 along the Z direction by etching through the hard mask layer 310 and the first dielectric layer 308. As shown in FIG. 3B, the first trenches 316 are connected to the conductive layer 304 along the Z direction. In some implementations, the semiconductor structure 300b does not include the conductive layer, where the first trenches 316 are connected to the semiconductor structure 302 along the Z direction. In some implementations, the sacrificial layer 314 and the second dielectric layer 312 are used as protective layers during the etching process to protect the hard mask layer 310 and the first dielectric layer 308 during the deepening of the first trenches 316. The sacrificial layer 314 and the second dielectric layer 312 are removed after the etching process to deepen the first trenches 316.

FIG. 3C illustrate a semiconductor structure 300c, which can be formed by removing the hard mask layer 310 through an etching process.

FIG. 3D illustrates a semiconductor structure 300d, which can be formed by filling a conductive material into the first trenches 316 to form via structures 318.

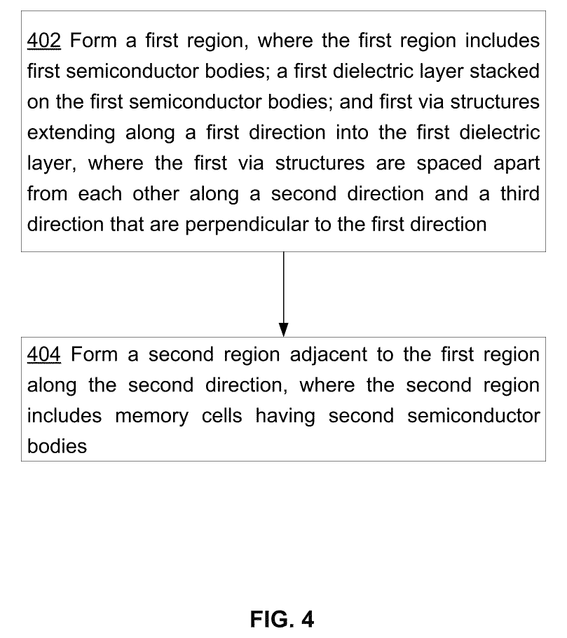

FIG. 4 illustrates a flow chart of an example process 400. The process 400 can be performed to form a semiconductor device (e.g., the semiconductor device 100 illustrated by FIG. 1). The process 400 can be described in view of FIGS. 3A – 3D. The process 400 can include one or more steps of the fabrication process of forming the semiconductor structures in FIGS. 3A – 3D. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a first region (e.g., the first region 102 of FIG. 1) is formed. The first region includes first semiconductor bodies (e.g., the first semiconductor body 214 of FIG. 2B); a first dielectric layer (e.g., the first dielectric layer 216 of FIG. 2B) stacked on the first semiconductor bodies; and first via structures (e.g., the first via structures 202 of FIG. 2B) extending along a first direction (e.g., the Z direction) into the first dielectric layer, where the first via structures are spaced apart from each other along a second direction (e.g., the Y direction) and a third direction (e.g., the X direction) that are perpendicular to the first direction.

At operation 404, a second region (e.g., the second region 104 of FIG. 1) adjacent to the first region is formed. The second region includes memory cells (e.g., the memory cells 232 of FIG. 2D) having second semiconductor bodies (e.g., the second semiconductor body 236 of FIG. 2D).

In some implementations, forming the first via structures in the first region includes providing a substrate including the first semiconductor bodies; depositing a dielectric material on the first semiconductor bodies to form the first dielectric layer; etching a portion of the first dielectric layer to form first holes (e.g., the first trenches 316 of FIG. 3A); and filling the first holes with a conductive material to form the first via structures.

In some implementations, a sum of areas of cross-sections of the first holes in a unit area of an overlay (OVL) measurement of the first region occupies at least 30% of the unit area, where the unit area is perpendicular to the first direction.

In some implementations, the first holes are arranged in rows extending along the second direction and in columns extending along the third direction, and a length of the rows of the first holes is less than or equal to a length of the first region along the second direction, and where a length of the columns of the first holes is at least 25 µm along the third direction.

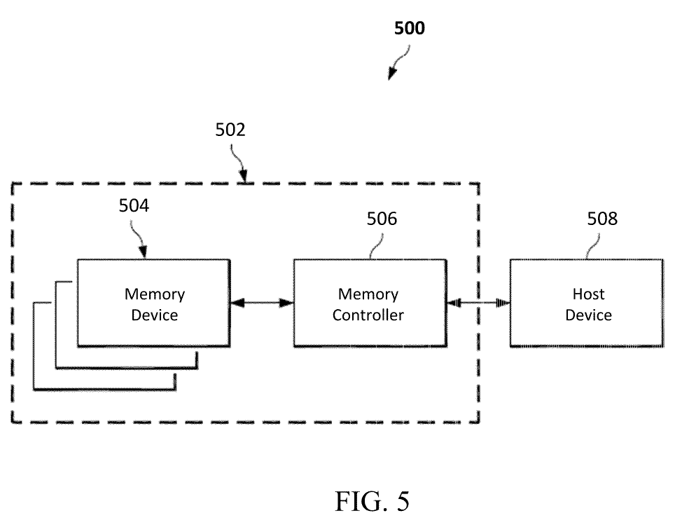

FIG. 5 illustrates a block diagram of a system 500 having one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as a 3D memory device depicted in FIGS. 1, 2A -2D. In some implementations, a 3D memory device 504 includes a DRAM memory. Memory controller 506 (a.k.a., a controller circuit) is coupled to 3D memory device 504 and host device 508. Consistent with implementations of the present disclosure, 3D memory device 504 can include a plurality of conductive interconnections through a cover layer that are in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via word lines. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single 3D memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first region, wherein the first region comprises:
first semiconductor bodies;
a first dielectric layer stacked on the first semiconductor bodies; and
first via structures extending along a first direction into the first dielectric layer, wherein the first via structures are spaced apart from each other along a second direction and a third direction that are perpendicular to the first direction; and
a second region adjacent to the first region along the second direction, wherein the second region comprises memory cells having second semiconductor bodies.

2. The semiconductor device of claim 1, wherein a sum of areas of cross-sections of the first via structures in a unit area of an overlay (OVL) measurement of the first region occupies at least 30% of the unit area, wherein the unit area is perpendicular to the first direction.

3. The semiconductor device of claim 1, wherein the first semiconductor bodies extend along the first direction, and wherein a portion of the first semiconductor bodies closer to the first dielectric layer are connected together along the second direction.

4. The semiconductor device of claim 1, wherein the first via structures are arranged in rows extending along the second direction and in columns extending along the third direction.

5. The semiconductor device of claim 4, wherein the rows of the first via structures are arranged in a staggered pattern.

6. The semiconductor device of claim 4, wherein a length of the rows of the first via structures is less than or equal to a length of the first region along the second direction, and wherein a length of the columns of the first via structures is at least 25 µm along the third direction.

7. The semiconductor device of claim 3, wherein the first region comprises:
a first conductive line stacked on the first semiconductor bodies, wherein the first conductive line is between the first semiconductor bodies and the first dielectric layer along the first direction, and wherein the first conductive line extends along the second direction; and
second conductive lines extending along the third direction, wherein at least one of the second conductive lines are between two adjacent first semiconductor bodies along the second direction.

8. The semiconductor device of claim 7, wherein, along the third direction, one or more of the second conductive lines are between two adjacent first via structures.

9. The semiconductor device of claim 1, wherein the memory cells in the second region are arranged in to one or more blocks, and
wherein each of the one or more blocks comprises a core region comprising an array of the memory cells and a surrounding region that surrounds the core region.

10. The semiconductor device of claim 9, wherein each of the one or more blocks further comprises:
a second dielectric layer stacked on the second semiconductor bodies of the memory cells;
a bit line stacked on the second semiconductor bodies, wherein the bit line is between the second semiconductor bodies and the second dielectric layer along the first direction, and wherein the bit line extends along the second direction; and
word lines extending along the third direction, wherein at least one of the word lines is between two adjacent second semiconductor bodies along the second direction.

11. The semiconductor device of claim 10, wherein the surrounding region comprises second via structures extending along the first direction,
wherein the second via structures extend through the second dielectric layer, and
wherein the second via structures are spaced apart from each other along the second direction and the third direction.

12. The semiconductor device of claim 11, wherein the bit line is coupled to a peripheral circuit through a corresponding one of the second via structures in the surrounding region, and
wherein each of the word lines is coupled to the peripheral circuit through a corresponding one of the second via structures in the surrounding region.

13. The semiconductor device of claim 11, wherein a sum of areas of cross-sections of the second via structures in a unit area of an OVL measurement of the surrounding region is less than or equal to 10% of an area of the unit area, wherein the unit area is perpendicular to the first direction.

14. The semiconductor device of claim 11, wherein, along the second direction, a distance between two adjacent first via structures in the first region is substantially same as a distance between two adjacent second via structures in the surrounding region of the second region.

15. The semiconductor device of claim 11, wherein an area of a cross-section of each of the first via structures is substantially equals to an area of a cross-section of each of the second via structures.

16. A method of forming a semiconductor device, the method comprising:
forming a first region, wherein the first region comprises:
first semiconductor bodies;
a first dielectric layer stacked on the first semiconductor bodies; and
first via structures extending along a first direction into the first dielectric layer, wherein the first via structures are spaced apart from each other along a second direction and a third direction that are perpendicular to the first direction; and
forming a second region adjacent to the first region along the second direction, wherein the second region comprises memory cells having second semiconductor bodies.

17. The method of claim 16, wherein forming the first via structures in the first region comprises:
providing a substrate comprising the first semiconductor bodies;
depositing a dielectric material on the first semiconductor bodies to form the first dielectric layer;
etching a portion of the first dielectric layer to form first holes; and
filling the first holes with a conductive material to form the first via structures.

18. The method of claim 17, wherein a sum of areas of cross-sections of the first holes in a unit area of an overlay (OVL) measurement of the first region occupies at least 30% of the unit area, wherein the unit area is perpendicular to the first direction.

19. The method of claim 17, wherein the first holes are arranged in rows extending along the second direction and in columns extending along the third direction, and
a length of the rows of the first holes is less than or equal to a length of the first region along the second direction, and wherein a length of the columns of the first holes is at least 25 µm along the third direction.

20. A memory system, comprising:
a memory device; and
a memory controller coupled to the memory device and configured to control the memory device,
wherein the memory device comprises:
a first region, wherein the first region comprises:
first semiconductor bodies;
a first dielectric layer stacked on the first semiconductor bodies; and
first via structures extending along a first direction into the first dielectric layer, wherein the first via structures are spaced apart from each other along a second direction and a third direction that are perpendicular to the first direction; and
a second region adjacent to the first region along the second direction, wherein the second region comprises memory cells having second semiconductor bodies.
